(19) United States
(12) Patent Application Publication
(10) Pub. No.: US 2012/0061705 A1
(43) Pub. Date: Mar. 15, 2012

(54) Method for Treating Metal Surfaces

(75) Inventors: Lenora M. Toscano, Bristol, CT (US); Ernest Long, Burlington, CT (US); Witold Paw, Sandy Hook, CT (US); Donna M. Kologe, Thomaston, CT (US); Katsutsugu Koyasu, Chigasaki-Shi (JP); Keisuke Nishu, Tokyo (JP)

(73) Assignee: MacDermid Acumen, Inc.

(21) Appl. No.: 13/229,210

(22) Filed: Sep. 9, 2011

Related U.S. Application Data
(63) Continuation of application No. 12/879,672, filed on Sep. 10, 2010.

(51) Int. Cl. H01L 33/46; B23K 31/02; B32B 15/04; B05D 5/12

(52) U.S. Cl. 257/98; 427/66; 228/180.22; 428/673; 257/E33.072

(57) ABSTRACT

A method for treating a metal surface to reduce corrosion thereon and/or to increase the reflectance of the treated surface, the method comprising a) plating a metal surface with an electroless nickel plating solution; and thereafter b) immersion plating silver on the electroless nickel plated surface, whereby corrosion of the metal surface is substantially prevented and/or the reflectance of the silver plated surface is substantially improved. The treating method is useful for increasing the solderability of the metal surface, for example, in electronic packaging applications.

### CROSS REFERENCE TO RELATED APPLICATIONS

This application is a continuation of U.S. application Ser. No. 12/879,672, filed Sep. 10, 2010, the subject matter of which is herein incorporated by reference in its entirety.

### FIELD OF THE INVENTION

The present invention is directed to a method of treating metal surfaces to reduce corrosion thereon and/or increase reflectance of the treated metal surfaces.

### BACKGROUND OF THE INVENTION

Printed circuit board (PCB) manufacturing processes typically comprise many steps, in part because of the increasing demand for enhanced performance. Surface circuits on PCBs usually include copper and copper alloy materials that are coated to provide good mechanical and electrical connection with other devices in the assembly. In the production of printed circuit boards, a first stage comprises preparing the circuit board and a second stage comprises mounting various components on the circuit board.

There are generally two types of components that are attachable to the circuit board: a) legged components, such as resistors, transistors, etc., which are attached to the circuit board by passing each of the legs through a hole in the board and then ensuring that the hole around the leg is filled with solder; and b) surface mount devices, which are attached to the surface of the board by soldering with a flat contact area or by adhesion with a suitable adhesive.

Plated through-hole printed circuit boards may generally be fabricated by a process comprising the following sequence of steps:
1) Drill holes through copper clad laminate;
2) Process boards through standard plated through hole cycle to plate electroless copper in the holes and on the surface;
3) Apply a plating mask;
4) Electrolytically plate copper to desired thickness in the holes and on the exposed circuitry;
5) Electrolytically plate tin in holes and on exposed circuitry to serve as an etch resist;
6) Strip the plating resist;
7) Etch the exposed copper (i.e., copper not plated with tin);
8) Strip the tin;
9) Apply, image and develop a soldermask such that the soldermask covers the substantially entire board surface except for the areas of connection; and
10) Apply protective solderable layer to the areas to be soldered.

Other sequences of steps may also be used and are generally well known to those skilled in the art. In addition, fresh water rinses may be interposed between each step. Other examples of sequences of steps that may be used to prepare the printed circuit boards in the first stage are described, for example, in U.S. Pat. No. 6,319,543 to Soutar et al., U.S. Pat. No. 6,656,370 to Toscano et al., and U.S. Pat. No. 6,815,126 to Fey et al., the subject matter of each of which is herein incorporated by reference in its entirety.

Solder masking is an operation in which the entire area of a printed circuit board, except solder pads, surface mount pads, and plated through-holes, is selectively covered with an organic polymer coating. The polymer coating acts like a dam around the pads to prevent the undesirable flow of solder during assembly and also improves the electrical insulation resistance between conductors and provides protection from the environment. The solder mask compound is typically an epoxy resin that is compatible with the substrate. The solder mask may be screen printed onto the printed circuit board in the desired pattern or may also be a photoimageable solder mask that is coated onto the surface.

The contact areas include wire-bonding areas, chip attach areas, soldering areas and other contact areas. Contact finishes must provide good solderability, good wire bonding performance and high corrosion resistance. Some contact finishes must also provide high conductivity, high wear resistance, and high corrosion resistance. A typical prior art contact finish coating may include an electrolytic nickel coating with an electrolytic gold layer on top, although other coatings are also known to those skilled in the art.

Soldering is generally used for making mechanical, electromechanical, or electronic connections to a variety of articles. The distinction between expected functions of the joints is important because each application has its own specific requirements for surface preparation. Of the three soldering applications, making electronic connections is the most demanding.

In the manufacture of electronic packaging devices such as printed circuit boards, connections of electronic components to a substrate are made by soldering the leads of the components to the through-holes, surrounding pads, lands and other points of connection (collectively, “Areas of Connection”) on the substrate. Typically the connections occur by wave soldering techniques. The electronic packaging devices may then receive other electronic units including, for example, light emitting diodes (LEDs), which can be soldered to, for example, electrodes on a printed circuit board. As used herein, “LED” refers to a diode that emits visible, ultraviolet, or infrared light. In modem production methods for light-emitting diodes (LEDs), the light-emitting layer sequence is often first grown on a growth substrate, subsequently applied to a new carrier, and then the growth substrate is detached. This method has on the one hand the advantage that growth substrates, in particular growth substrates suitable for the production of nitride compound semiconductors, which are comparatively expensive, can be reused. This method, referred to as thin-film technology, also has the advantage that the detachment of the original substrate allows the disadvantages of the latter, such as for example a low electrical conductivity and increased absorption of the radiation generated or detected by the optoelectronic device, to be avoided.

A further technology for the production of highly efficient LEDs is so-called flip-chip technology. Such a device is disclosed for example in U.S. Pat. No. 6,514,782. Described therein is a radiation-emitting semiconductor chip which is connected to a carrier substrate both by the n contact and by the p contact by means of a direct soldered connection.

Both in thin-film technology and in flip-chip technology, it is advantageous to form the contact between the semiconductor chip and the carrier substrate as a reflecting contact. In this way, penetration of the radiation generated or detected by an optoelectronic device into the contact is avoided and consequently the absorption losses are reduced.

The thin-film semiconductor body is for example connected by the electrical contact to a carrier body which would be located above the solder layer. The materials of the solder layer and of the carrier body are preferably made to match each other in such a way that they can form an alloy, in particular a eutectic alloy, that is to say no metallurgical barrier exists between the solder layer and the carrier body. The material of the carrier body can begin to melt during the soldering operation and consequently serve as a material reservoir for the forming of a eutectic alloy.

In one process, as described in U.S. Patent Publication No. 2004/0256632 to Stein et al., a semiconductor chip may have on its surface, for example, a material from the group of nitride compound semiconductors, a nitride compound semiconductor being understood as meaning a nitride compound of elements of the third and/or fifth main group, in particular GaN, AlGaN, InGaN, AlInGaN, AlN or InN.

A mirror layer is applied to the semiconductor chip. The mirror layer contains a metal or a metal alloy, preferably one of the following metals: silver, aluminum or platinum. The mirror layer is preferably between 70 nm and 130 nm thick. The mirror layer reflects the radiation that is incident from the direction of the optoelectronic semiconductor chip and thereby prevents the absorption of this radiation in the electrical contact. The minor layer also establishes an ohmic contact with respect to the semiconductor. For example, a Pt/Al combination may be used for establishing an ohmic contact on an InGaN semiconductor. On p-GaN semiconductor material, a silver layer is suitable for establishing an ohmic contact.

Furthermore, a protective layer may be applied to the mirror layer in order to protect it from corrosion in further process steps.

Thus, it is desirable to increase the solderability of a metal surface that is used in electronic packaging applications including those involving printed circuit boards and LEDs.

To facilitate these soldering operations, through-holes, pads, lands and other points of connection are arranged so that they are receptive to the subsequent soldering processes. Thus, these surfaces must be readily wettable by the solder to permit an integral conductive connection with the leads or surfaces of the electronic components. Because of these needs, printed circuit fabricators have devised various methods of preserving and enhancing the solderability of these surfaces.

One means of providing good solderability of the surfaces in question is to provide the surfaces with a pre-coating of solder. In printed circuit fabrication, however, this method has several drawbacks. In particular, because it is not easy to selectively provide these areas with solder, all conductive areas of the board must be solder plated, which can cause severe problems with the subsequent application of solder mask.

Various attempts have been made to selectively apply solder to the necessary areas only. For example, U.S. Pat. No. 4,978,423, the subject matter of which is herein incorporated by reference in its entirety, involves the use of organic etch resists over the solder plated areas of connection followed by selective stripping of tin-lead from the copper traces before application of the solder mask. U.S. Pat. No. 5,160,579, the subject matter of which is herein incorporated by reference in its entirety, describes other examples of known selective solder processes.

Soldering directly to copper surfaces can be difficult and inconsistent. These problems are due mainly to the inability to keep the copper surfaces clean and free of oxidation throughout the soldering operation. Various organic treatments have been developed to preserve copper surfaces in a readily solderable state. For example, U.S. Pat. No. 5,173,130 to Kinoshita, the subject matter of which is herein incorporated by reference in its entirety, describes the use of certain 2-alkylbenzimidazoles as copper pre-fluxes to preserve the solderability of the copper surfaces. Treatments such as those described by Kinoshita have proven successful but there is still a need to improve their reliability.

Another means of arranging good solderability of these surfaces is to plate them with a final finish coating of gold, palladium or rhodium. For example, U.S. Pat. No. 5,235,139 describes a method for achieving this metal final finish by plating the copper areas to be soldered with electroless nickel-boron, followed by a precious metal coating such as gold. In addition, U.S. Pat. No. 4,940,181 describes the plating of electroless copper, followed, by electrolytic copper, followed by nickel followed by gold as a solderable surface and U.S. Pat. No. 6,776,828 describes the plating of electroless copper followed by immersion gold. These processes work well but are time consuming and relatively expensive.

Still another means of arranging good solderability of these surfaces is to electrolessly plate them with a final coating of silver. For example, U.S. Pat. No. 5,322,553 and U.S. Pat. No. 5,318,621, the subject matter of each of which is herein incorporated by reference in its entirety, describe methods of treating copper clad printed circuit boards by coating them with electroless nickel then subsequently plating them with electroless silver. The electroless silver bath plates on a surface of a support metal to give a thick deposit.

As discussed in U.S. Pat. No. 6,773,757 and U.S. Pat. No. 5,935,640, the subject matter of each of which is herein incorporated by reference in its entirety, it is known that immersion silver deposits are excellent solderability preservatives, which are particularly useful in the fabrication of printed circuit boards. Immersion plating is a process Which results from a replacement reaction whereby the surface being plated dissolves into solution and at the same time the metal being plated deposits from the plating solution onto the surface. The immersion plating typically initiates without prior activation of the surfaces. The metal to be plated is generally more noble than the surface metal. Thus immersion plating is usually significantly easier to control and significantly more cost effective than electroless plating, which requires sophisticated auto-catalytic plating solutions and processes for activation of the surfaces prior to plating.

The use of immersion silver deposits can be problematic because of the possibility of solder mask interface attack (SMIA) in which galvanic attack may erode the copper trace at the interface between the solder mask and the copper trace. SMIA is also referred to as solder mask crevice corrosion and galvanic attack at the solder mask interface. The problem concerns a galvanic attack at the solder mask-copper interface, and this interfacial galvanic attack arises as a result of the solder mask-copper interfacial structure and the immersion plating mechanism.

Galvanic corrosion is caused by the junction of two dissimilar metals. Differences in the metal can be seen as composition of the metal itself varying, or differences in grain boundaries, or localized shear or torque from the manufacturing process. Almost any lack of homogeneity of the metal surface or its environment may initiate a galvanic corrosion attack, causing a difference in potential. Contact between dissimilar metals also causes galvanic current to flow, due to the difference in potential of the two or more different metals. Galvanic corrosion can occur when one metal is coated with a more noble metal, for example silver over copper, and any exposed copper can accelerate this process as well. Higher failure rates and accelerated corrosion are seen in environments that have high levels of reduced sulfur gases such as elemental sulfur and hydrogen sulfide.

The formation of a silver layer is also desirable in the manufacture of LEDs. As described, for example, in U.S. Pat. Pub. No. 2004/0256632 to Stein et al., the subject matter of which is herein incorporated by reference in its entirety, it is desirable to form a reflective contact between an optoelectronic semiconductor chip, for example an LED, and a carrier substrate so that penetration of radiation generated or detected by the optoelectronic semiconductor chip into the contact is avoided and absorption losses are reduced. Stein describes arranging a very thin layer containing platinum, palladium, or nickel between a semiconductor layer containing a nitride compound and a reflective layer containing silver or gold. U.S. Pat. Pub. No. 2007/0145396 to Wantanabe, the subject matter of which is herein incorporated by reference in its entirety, describes improving the light extraction efficiency of an LED and thereby increase the life and power of the LED while decreasing power consumption, by arranging a light reflective layer comprising a silver alloy between a semiconductor layer, formed by laminating a first conductive layer, an active layer and a second conductive layer on a transparent substrate, and a protective layer.

While various methods have been suggested for treating metal surfaces to prevent corrosion thereon and/or increase reflectance of the treated metal surface, there remains a need for addition processes for preventing corrosion and/or increasing reflectance.

### SUMMARY OF THE INVENTION

It is an object of the present invention to provide an improved means of reducing corrosion of underlying metal surfaces.

It is another object of the present invention to provide an improved means of preventing galvanic corrosion of such metal surfaces.

It is still another object of this invention to propose an improved means for preserving and enhancing the solderability of metal surfaces.

It is still another object of the invention to eliminate copper pores in silver deposits that are susceptible to tarnish and corrosion.

It is still another object of the invention to substantially eliminate migration of copper through silver deposits on printed, circuit boards, electronic packaging and LEDs.

It is still another object of the invention to increase reflectance of silver surfaces during the manufacture of LEDs.

To that end, the present invention relates to a method of treating a metal surface, the method comprising the steps of:
a) preparing a metal surface to accept electroless nickel plating thereon;
b) plating the metal surface with an electroless nickel plating solution; and thereafter
c) immersion plating silver on the electroless nickel plated surface,
whereby corrosion of the metal surface is substantially prevented and/or reflectance of the silver plated surface is substantially improved.

### DETAILED DESCRIPTION OF THE PREFERRED EMBODIMENTS

The present invention relates to a method of treating a metal surface, the method comprising the steps of:
a) preparing a metal surface to accept nickel plating thereon;
b) plating the metal surface with a nickel plating solution; and thereafter
c) immersion plating silver on the nickel plated surface,
wherein the nickel plated on the metal surface comprises either from 2% to 12% by weight phosphorous or from 0.0005% to 0.1% by weight sulfur.

The metal surface may be any metal which is less electropositive than silver, including, for example, zinc, iron, tin, nickel, lead or copper and alloys of the foregoing. In a preferred embodiment, the metal surface is a copper or copper alloy surface.

Preferably, prior to contacting the metal surface with the plating composition compositions, the metal surface is cleaned. For example, cleaning may be accomplished using an acidic cleaning composition or other such cleaning composition that is well known in the art.

The nickel plating is preferably accomplished electrolessly but it can also be plated electrolytically. Electroless nickel plating is an autocatalytic or chemical reduction of nickel ions to nickel which is then deposited on a substrate and can be used upon any metal surface upon which nickel can be plated.

In order to successfully plate nickel on certain metal surfaces, it may be necessary to activate the surfaces with a precious metal activator prior to contacting the surfaces with the electroless nickel plating bath. The precious metal activator typically comprises colloidal or ionic palladium, gold or silver and is performed before the electroless step.

For example, when the metal surface comprises copper or copper alloy, preparing the surface to accept electroless nickel plating thereon may comprise (i) a precious metal activator before an electroless nickel phosphorus bath, or (ii) use of a dimethylamino borane pre-dip to create a very thin nickel layer before an electroless nickel phosphorus bath. In either instance, an adherent and uniform deposit is formed on the metal surface.

Optionally, the metal surface may also be microetched to increase the magnitude and reliability of the subsequent bond. In the case of copper or copper alloy metal surfaces, the microetch may comprise (i.) a peroxide-sulfuric microetch, (ii) a cupric chloride microetch, or (iii) a persulfate microetch. In each case, it is preferable for the microetch to uniformly roughen the metal surface. The time and temperature of the contact with the microetchant may vary depending, for example, upon the type of microetchant being used and the characteristics of the metal surface with the goal being the attainment of a uniformly rough metal surface.

After microetching, and before contact with the plating bath, the metal surface may be activated with a precious metal activator, as discussed above, to coat the metal surface with catalytic precious metal sites which are capable of initiating the subsequent electroless plating.

The metal surface is then contacted with an electroless nickel plating bath, preferably for a time and at a temperature sufficient to plate about 2 to about 50 microinches of nickel, more preferably from about 100 to about 250 microinches of nickel.

In one embodiment, a suitable electroless nickel plating bath for use in the present invention comprises:
a) a source of nickel ions;
b) a reducing agent;
c) a complexing agent;
d) one or more bath stabilizers; and
e) one or more additional additives.

The source of nickel ions can be any suitable source of nickel ions, and is preferably a nickel salt selected from the group consisting of nickel bromide, nickel fluoroborate, nickel sulfonate, nickel sulfamate, nickel alkyl sulfonate, nickel sulfate, nickel chloride, nickel acetate, nickel hypophosphite and combinations of one or more of the foregoing. In a preferred embodiment the nickel salt is nickel sulfamate. In another preferred embodiment, the nickel salt is nickel sulfate.

Reducing agents typically include borohydride and hypophosphite ions. Typically, electroless nickel plating is carried out utilizing hypophosphite ions as the reducing agent, with sodium hypophosphite being the most preferable. Other reducing agents include sodium borohydride, dimethylamine borane, N-diethylamine borane, hydrazine and hydrogen, by way of example and not limitation.

The stabilizers in the solution may be metallic (inorganic) or organic. Metallic stabilizers commonly used in electroless nickel plating solutions include Pb, Sn, or Mo compounds, such as lead acetate. Organic stabilizers commonly used include sulfur compounds (“S compounds”), such as thiourea. Complexing agents include citric acid, lactic acid, or malic acid. Sodium hydroxide may also be included in the electroless nickel bath to maintain the pH of the solution.

As described herein the electroless nickel plating solution may include one or more additives selected from sulfur and/or phosphorus. Sulfur is preferably usable in the plating solution as a divalent sulfur and phosphorus is typically usable in the plating solution as a hypophosphite. If divalent sulfur is present in the electroless nickel plating solution, it is preferable that it be present at a concentration of about 0.1 ppm to about 3 ppm, most preferably from about 0.2 ppm to about 1 ppm, not including the sulfur present from the source of acidity such as sulfuric acid, sulfuric acid or methane sulfonic acid. Furthermore, the inventors have found that if nickel sulfamate is used as the nickel salt in accordance with the present invention, at least a minimal amount of sulfur and/or phosphorus should be included in the electroless nickel plating bath. It is important that the nickel, plated on the metal surface, comprise about 2 percent by weight to about 12 percent by weight phosphorus and/or 0.0005% by weight sulfur to 0.1% by weight sulfur. It has unexpectedly been found that the inclusion of the foregoing amounts of phosphorous and/or sulfur are beneficial to achieving an improved immersion silver deposit.

Nickel ions are reduced to nickel in the electroless nickel plating bath by the action of chemical reducing agents which are oxidized in the process. The catalyst may be the substrate or a metallic surface on the substrate, which allows the reduction-oxidation reaction to occur with the ultimate deposition of nickel on the substrate.

The electroless plating deposition rate is further controlled by selecting the proper temperature, pH and metal ion/reducer concentrations. Complexing agents may also be used as catalyst inhibitors to reduce the potential for spontaneous decomposition of the electroless bath.

The total thickness of electroless nickel plated on the metal surface is typically in the range of about 1 to 50 microinches, preferably in the range of about 100 to about 250 microinches.

Once a layer of electroless nickel has been plated on the metal surface, the electroless nickel plated metal surface is thereafter immersion silver plated to provide a layer of silver thereon. As discussed above, immersion silver deposits are excellent solderability preservatives and are particularly useful in the fabrication of printed circuit boards. The solderability achieved by following electroless nickel plating with immersion silver plating in accordance with the present invention results in an unexpectedly large reduction of galvanic corrosion on the surfaces of the circuits, a reduction of copper pores Which are susceptible to tarnish and corrosion, and an increase in the process window for bonding applications. This is beneficial because, in printed circuit applications, for example, the surfaces are wire bondable. Additionally, the process of the present invention results in uniform silver coverage and increased reflectance of the silver surface.

In one embodiment, the immersion silver plating bath of the present invention comprises:
a) a soluble source of silver ions;
b) an acid;
c) an oxidant; and
d) optionally, but preferably, an imidazole or imidazole derivative.

The silver immersion plating solution generally contains a soluble source of silver ions in an acid aqueous matrix. The soluble source of silver ions can be derived from a variety of silver compounds, including for example organic or inorganic silver salts. In a preferred embodiment, the source of silver ions is silver nitrate. The concentration of silver in the plating solution can generally range from about 0.1 to 25 grams per liter, but is preferably in the range of about 0.5 to 2 grams per liter.

A variety of acids are suitable for use in the silver immersion plating solution, including, for example, fluoboric acid, hydrochloric acid, phosphoric acid, methane sulfonic acid, nitric acid and combinations of one or more of the foregoing. In one embodiment, methane sulfonic acid or nitric acid is used. ^{The} concentration of acid in the plating solution generally ranges from about 1 to 150 grams per liter but is preferably in the range of about 5 to 50 grams per liter.

The silver immersion plating solution also comprises an oxidant in order to create a uniform silver covering on the electroless nickel plated substrate. Nitro aromatic compounds such as sodium meta-nitrobenzenesulfonate, para-nitrophenol, 3,5-dinitrosalicylic acid, and 3,5-dinitrobenzoic acid are preferred in this regard. In a preferred embodiment, the dinitro compound is 3,5-dinitrosalicylic acid. The concentration of the oxidant in the solution can range from about 0.1 to 25 grams per liter, but is preferably from about 0.5 to 2 grams per liter.

In order to further reduce the tendency for immersion silver plates to electromigrate in the application proposed, certain additives may also be included in the plated deposit, either by incorporation of the additives in the plating bath itself or by subsequent treatment of the plated surface with the additives. These additives may be selected from the group consisting of fatty amines, fatty acids, fatty amides, quaternary salts, amphoteric salts, resinous amines, resinous amides, resinous acids and mixtures of the foregoing. Examples of the additives are described, for example, in U.S. Pat. No. 7,267,259, the subject matter of which is herein incorporated by reference in its entirety. The concentration of the foregoing additives in the immersion silver plating bath or in the subsequent surface treatment composition typically range from 0.1 to 15 grams per liter but is preferably from 1 to 5 grams per liter.

In addition, as described in U.S. Pat. No. 7,631,793, the subject matter of which is herein incorporated by reference in its entirety, an imidazole or imidazole derivative may also optionally be included in the immersion plating bath of the present invention to make the plate brighter, smoother and more cohesive.

The immersion silver plating bath is typically maintained at a temperature of about room temperature to about 200° F., more preferably at about 80° F. to about 120° F. The article to be plated may be immersed in the plating solution fur a suitable amount of time to achieve the desired plating thickness of the deposit, which is typically in the range of about 1 to 5 minutes.

The immersion silver solution plates a thin layer of silver onto the metal surface. In one embodiment, the resultant silver coating is from about 1 to 100 micro inches thick, preferably from about 10 to 60 micro inches thick for effective enhancement and preservation of the solderability of the surface.

Although the process described herein is effective in soldering various metal surfaces, it is particularly useful in soldering copper surfaces, such as Areas of Connection on electronic packaging devices such as printed circuit boards. By preventing corrosion on the printed circuit boards, the useful life of the device can be extended. Furthermore, by eliminating corrosion, soldering problems can be substantially eliminated, which is a major benefit for board, circuit and component manufacturers.

The process described herein is also effective in silver plating LEDs and in preparing LEDs to accept soldering thereon, for example for soldering to electronic packaging devices including printed circuit boards. Suitable for example for the patterning of an electrical contact according to the invention are known methods of wet-chemical patterning. It is possible for copper to migrate through silver deposits as a function of heat in LED applications, thus decreasing the surface reflectance. Thus, the process described herein produces a surface in which copper migration through the silver deposit is at least substantially eliminated resulting in increased reflectivity, which is particularly beneficial for use in LED applications. In one embodiment, the process described herein provides a silver surface on an LED with a reflectance of at least 80 percent.

As described herein, the process of the present invention can be used to electrolessly deposit nickel onto a semiconductor chip. The process of the present invention can also be used to deposit electroless nickel and immersion silver upon a semiconductor LED that has been formed by laminating a first conductive layer, an active layer, and a second conductive layer on a transparent substrate in that order as is known in the art.

The process of the present invention has also been shown to at least substantially eliminate galvanic corrosion from the underlying copper substrate. In addition, the process of the present invention substantially eliminates copper pores in the silver deposit that are susceptible to tarnish corrosion and further at least substantially eliminates migration of copper through the silver deposit. As a result, the process of the present invention also increases the processing window for wire bonding applications because any oxidized copper encountered during wire bonding results in a non-bondable surface.

Finally, while the present invention as described herein utilizes electroless nickel, it is also possible that the nickel barrier can be provided using an electrolytic nickel deposit or that the electroless nickel plating bath may comprise a nickel alloy or, in the alternative, another suitable electroless plating metal may be used in place of electroless nickel in the invention described herein.

While the invention has been described above with reference to specific embodiments thereof, it is apparent that many changes, modifications, and variations can be made without departing from the inventive concept disclosed here. Accordingly, it is intended to embrace all such changes, modifications, and variations that fall within the spirit and broad scope of the appended claims. All patent applications, patents, and other publications cited herein are incorporated by reference in their entirety.

1-21. (canceled)

22. A process for treating a metal surface, said process comprising the steps of:
a) providing a carrier substrate configured for having mounted thereon a light emitting diode;
b) patterning a reflective layer over the carrier substrate, wherein the reflective layer comprises a copper layer that is coated with a nickel layer and a silver layer;
wherein the nickel layer is formed using an electroless nickel plating process;
wherein the silver layer is formed on the nickel layer by an electroless deposition process,
wherein the resultant silver coating is from about 1 to 100 microinches thick;
wherein the silver layer results in a uniform silver coverage and increased reflectance of the silver surface; and
wherein the silver layer provides a solderable surface for mounting of the light emitting diode thereon.

23. The process according to claim 22, wherein the copper layer is patterned to form at least one electrode on the carrier substrate.

24. The process according to claim 22, wherein the silver layer is formed by an immersion silver plating process.

25. The process according to claim 22, wherein the silver layer has a thickness of between about 10 to 60 microinches.

26. The process according to claim 22, wherein the light emitting diode is mounted on the carrier substrate by soldering.

27. The process according to claim 22, wherein the copper-nickel-silver contact prevents penetration of radiation generated or detected by the light emitting diode, whereby absorption losses are avoided.

28. The process according to claim 22, wherein the light emitting diode is a flip-chip light emitting diode, which is connected to the carrier substrate by an n-contact and a p-contact by means of a solder connection.

29. The process according to claim 22, wherein the copper-nickel-silver contact is a thermal pad that prevents penetration of radiation generated or detected by the light emitting diode, and wherein light emitting diode is connected to the carrier substrate by an n-contact and a p-contact by means of a solder connection.

30. (canceled)

31. (canceled)

32. The process according to claim 22, further comprising forming one or more copper-nickel-silver contact pads on the carrier substrate for electrical connection to a circuit board on which the substrate is to be mounted.

33. The process according to claim 22, further comprising mounting a plurality of light emitting diodes on the copper-nickel-silver mounting pad.

34. The process according to claim 22, wherein a bottom metal layer of the light emitting diode is bonded to the copper-nickel-silver mounting pad.

35. A structure comprising:
a carrier body configured for having mounted thereon a light emitting diode, the light emitting diode having a footprint;
a reflective layer patterned over the carrier substrate, wherein the reflective layer comprises a copper layer coated with a nickel layer and a silver layer;
wherein the nickel layer is formed using an electroless nickel plating process;
wherein the silver layer is formed on the nickel layer by an electroless deposition process,
wherein the resultant silver coating is from about 1 to 100 microinches thick;
wherein the silver layer results in a uniform silver coverage and increased reflectance of the silver surface; and
wherein the silver layer provides a solderable surface for mounting of the light emitting diode thereon.

36. The structure according to claim 35, comprising a bottom metal layer of the light emitting diode bonded to the copper-nickel-silver mounting pad.

37. The structure according to claim 35, further comprising one or more copper-nickel-silver contact pads formed on the submount for carrying current to a circuit board on which the substrate is to be mounted.

38. The structure according to claim 35, wherein the silver layer has a thickness of between about 10 to 60 microinches.

39. The structure according to claim 35, wherein the copper-nickel-silver contact prevents penetration of radiation generated or detected by the light emitting diode, whereby absorption losses are avoided.

40. The structure according to claim 35, wherein the light emitting diode is a flip-chip light emitting diode, which is connected to the carrier substrate by an n-contact and a p-contact by means of a solder connection.

41. The structure according to claim 35, wherein the copper-nickel-silver contact is a thermal pad that prevents penetration of radiation generated or detected by the light emitting diode, and wherein the light emitting diode is connected to the carrier substrate by an n-contact and a p-contact by means of a solder connection.

42. (canceled)
